(19) United States
(12) Patent Application Publication
(10) Pub. No.: US 2021/0040597 A1
(43) Pub. Date: Feb. 11, 2021

(54) HIGH-TEMPERATURE-RESISTANT HARD COMPOSITE COATING, PREPARATION METHOD THEREOF, AND COATED CUTTER

(71) Applicant: LINGNAN NORMAL UNIVERSITY, Guangdong (CN)

(72) Inventors: Changwei ZOU, Guangdong (CN); Shimin CHEN, Guangdong (CN); Zesong WANG, Guangdong (CN)

(21) Appl. No.: 16/650,247

(22) PCT Filed: Sep. 25, 2018
(86) PCT No.: PCT/CN2018/107206

§ 371 Date: Mar. 24, 2020

(30) Foreign Application Priority Data
Oct. 10, 2017 (CN) 201710934135.9

(51) Int. Cl. C23C 14/06; C23C 28/04; C23C 14/35; C23C 14/32

(52) U.S. Cl. CPC C23C 14/0641; C23C 28/044; B82Y 30/00; C23C 14/325; C23C 14/35

(57) ABSTRACT

A high-temperature-resistant hard composite coating is provided, and includes a CrN transition layer and a nanocomposite layer disposed on the surface of a substrate in sequence. The nanocomposite layer comprises AlCrSiN layers and MeN layers alternately arranged on the surface of the CrN transition layer in sequence. Me comprises W, Nb, or Hf. Also provided are a method for preparing the high-temperature-resistant hard composite coating, and a coated cutter.

### CROSS REFERENCE TO RELATED APPLICATIONS

This application claims priority to Chinese Patent Application No. 201710934135.9 entitled “HIGH-TEMPERATURE-RESISTANT HARD COMPOSITE COATING, PREPARATION METHOD THEREOF, AND COATED CUTTER”, filed before China's State Intellectual Property Office on Oct. 10, 2017, the entire contents of which are incorporated herein by reference.

### TECHNICAL FIELD

The present invention relates to the technical field of hard coatings, and particularly relates to a high-temperature-resistant hard composite coating, a preparation method thereof and a coated cutter.

### BACKGROUND

Hard coating is an effective way for performing material surface strengthening, exerting material potential and increasing production efficiency, and is a kind of surface coating, and which refers to a surface coating that is deposited on the surface of a substrate by a physical or chemical method and has microhardness greater than a certain special value. Hard coating has been widely applied to the cutting industry, die industry, geological drilling, textile industry, machinery manufacturing and aerospace field, and plays a more and more important role. Application of the hard coating in the cutting industry not only includes machining of common cutting tools, such as cutters, drill bits and other hard-to-machine materials, but also may increase cutting precision, exhibits the advantages of being superhard, tough, wear-resistant, self-lubricating and the like, and thus is regarded as a revolution of the cutting history.

Nanometer multi-layer composite coatings are widely applied in the cutter industry. Hard protective coatings in an early stage, such as simple binary TiN and TiC coatings, are widely applied in many fields due to high physical wear resistance, low friction coefficient and abrasive wear resistance. However, the high temperature oxidation resistance of the foregoing coatings are poor, and as a result, the coatings cannot meet the use requirement in the field of high-speed cutting. Although many researchers doped Al, Cr and other elements on the basis of a simple coating to improve the oxidation resistance effect of the coating, the hardness and friction and wear resistance of the coatings in a high temperature condition are still poor, resulting in short service life of cutters, and thus the modern requirement of high-speed machining of cutters still cannot be met.

### SUMMARY

The present invention is directed to provide a high-temperature-resistant hard composite coating, a preparation method thereof and a coated cutter. The high-temperature-resistant hard composite coating can still keep good hardness, low friction coefficient and friction and wear resistance in a high temperature condition, and is long in service life when being applied to the surface of a cutter.

In order to solve the foregoing technical problem, the present invention adopts the following technical scheme:

A hard high-temperature-resistant composite coating includes a CrN transition layer and a nanocomposite layer disposed on the surface of a substrate in sequence. The nanocomposite layer including AlCrSiN layers and MeN layers alternately arranged on the surface of the CrN transition layer in sequence, and the Me including W, Nb, or Hf.

Optimally, the thickness of each AlCrSiN layer is independently 10˜15 nm.

Optimally, the AlCrSiN layer contains 34˜42 at. % of Al, 13˜20 at. % of Cr, 5˜9 at. % of Si and 33˜47 at. % of N according to atomic percent.

Optimally, the AlCrSiN layer is of a nanocomposite structure including nanocrystalline CrN, amorphous Si₃N₄ and amorphous AN.

Optimally, the thickness of each MeN layer is independently 4˜10 nm.

Optimally, the MeN layer contains 48˜60 at. % of Me and 52˜40 at. % of N according to atomic percent.

Optimally, the MeN layer includes one out of nanocrystallines of WN, NbN and HfN.

Optimally, the thickness of the nanocomposite layer is 2˜5 μm.

Optimally, the thickness of the CrN transition layer is 50˜200 nm.

The present invention also provides a preparation method of the high-temperature-resistant hard composite coating according to the foregoing technical scheme, including the following:

(1) depositing a CrN transition layer on the surface of a substrate; and

(2) alternately depositing AlCrSiN layers and MeN layers in sequence on the surface of the CrN transition layer in step (1), to obtain a high-temperature-resistant hard composite coating.

Optimally, deposition in step (1) is cathode arc ion plating deposition.

Optimally, deposition of the AlCrSiN layer in step (2) is multi-arc ion plating deposition, and deposition of the MeN layer is high power pulse magnetron sputtering deposition.

The present invention also provides a coated cutter, including a cutter substrate and a coating disposed on the surface of the cutter substrate. The coating being a high-temperature-resistant hard composite coating according to the foregoing technical scheme or a high-temperature-resistant hard composite coating prepared by a preparation method according to the foregoing technical scheme.

The high-temperature-resistant hard composite coating provided by the present invention includes a CrN transition layer and a nanocomposite layer disposed on the surface of a substrate in sequence, the nanocomposite layer including AlCrSiN layers and MeN layers alternately arranged on the surface of the CrN transition layer in sequence, and the Me including W, Nb, or Hf. The high-temperature-resistant hard composite coating provided by the present invention takes CrN as a transition layer, to strengthen a binding force between a substrate and a nanocomposite layer. Alternately arranged AlCrSiN layers and MeN layers have adaptivity, W—O, Nb—O and Hf—O friction oxides with a lubricating effect may be rapidly formed under a high temperature condition (higher than 800° C.) due to doping of metal elements such as W, Nb and Hf. These oxides play a protective role for the interior of a coating while being formed on the surface of a cutter, so as to still keep physical and mechanical performances of good hardness, low friction coefficient and friction and wear resistance under a high temperature condition. Experimental results show that in the following cutting conditions: cutting speed being 350 m/min; workpiece material being H13 (HRC55˜57); feed rate being 0.06 mm/flute; depth being 0.3 mm; and side milling, the average service life of the high-temperature-resistant hard composite coating provided by the present invention is 162.0 m, which is obviously prolonged in comparison with the average service life of a cutter with an AlCrSiN coating in same conditions.

### BRIEF DESCRIPTION OF THE DRAWINGS

FIG. 1 is a schematic structure diagram of a high-temperature-resistant hard composite coating of the present invention, wherein 1 is a substrate, 2 is a CrN transition layer, 3 is a nanocomposite layer, 4 is an AlCrSiN layer, and 5 is an MeN layer; and

FIG. 2 is an XRD spectrum of a nanocomposite layer in the high-temperature-resistant hard composite coating of embodiment 1 of the present invention.

### DESCRIPTION OF THE EMBODIMENTS

The following further describes the present invention in combination with embodiments and drawings.

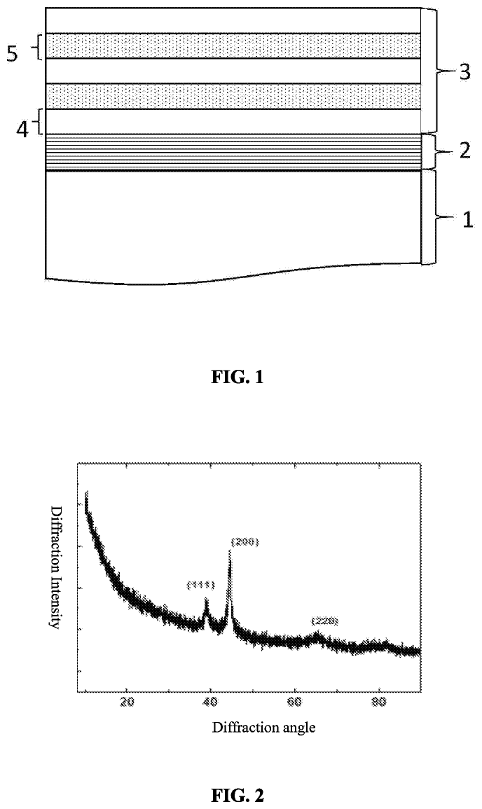

The present invention provides a high-temperature-resistant hard composite coating, as shown in FIG. 1, including a CrN transition layer 2 and a nanocomposite layer 3 disposed on the surface of a substrate 1 in sequence. The nanocomposite layer 3 includes AlCrSiN layers 4 and MeN layers 5 alternately arranged on the surface of the CrN transition layer 2 in sequence.

The high-temperature-resistant hard composite coating provided by the present invention includes a CrN transition layer 2 disposed on the surface of a substrate 1. According to the present invention, the thickness of the CrN transition layer is optimally 50˜200 nm, more optimally, 100˜150 nm, and most optimally, 120˜130 nm. According to the present invention, the CrN transition layer optimally contains 45˜64 at. % of Cr and 55˜36 at. % of N according to atomic percent, more optimally, contains 48˜55 at. % of Cr and 52˜45 at. % of N. According to the present invention, the CrN transition layer is disposed between the substrate and the nanocomposite layer, is matched with the substrate and the nanocomposite layer, and operates to strengthen a binding force between the two, and reduces fatigue and internal stress of the coating.

The high-temperature-resistant hard composite coating provided by the present invention includes a nanocomposite layer disposed on the surface of the CrN transition layer. The nanocomposite layer includes AlCrSiN layers and MeN layers alternately arranged on the surface of the CrN transition layer in sequence, and the Me includes W, Nb, or Hf. According to the present invention, an outermost layer of the high-temperature-resistant hard composite coating is optimally an MeN layer. According to the present invention, the thickness of each AlCrSiN layer is optimally 10˜15 nm independently, more optimally, 12˜13 nm. According to the present invention, the thickness of the MeN layer is optimally 4˜10 nm independently, more optimally, 6˜8 nm. According to the present invention, the thickness of the nanocomposite layer is optimally 2˜5 μm, more optimally, 3˜4 μm.

According to the present invention, the AlCrSiN optimally contains 34˜42 at. % of Al, 13˜20 at. % of Cr, 5˜9 at. % of Si and 33˜47 at. % of N according to atomic percent, more optimally, contains 36˜40 at. % of Al, 15˜18 at. % of Cr, 6˜8 at. % of Si and 38˜42 at. % of N. According to the present invention, the AlCrSiN layer is optimally of a nanocomposite structure including nanocrystalline CrN, amorphous Si₃N₄ and amorphous AN. According to the present invention, a grain size of the nanocrystalline CrN is 2˜10 nm, more optimally, 3˜5 nm. According to the present invention, the AlCrSiN layer has characteristics of high hardness and oxidation resistance, and meanwhile has a nanocomposite structure, so as to promote diffusion among elements in a high-speed cutting state, and promote the cutting performance of the overall coating.

According to the present invention, the MeN layer optimally contains 48˜60 at. % of Me and 52˜40 at. % of N according to atomic percent, more optimally, contains 50˜55 at. % of Me and 55˜50 at. % of N. According to the present invention, the MeN layer optimally comprises one out of nanocrystallines of WN, NbN and HfN. According to the present invention, a grain size of the MeN layer is optimally 3˜8 nm, more optimally, 4˜5 nm. According to the present invention, W, Nb or Hf in metal elements of the MeN layer can rapidly form W—O, Nb—O and Hf—O friction oxides with a lubricating effect under a high temperature condition (higher than 800° C.), and these oxides play a protective role for the interior of a coating while being formed on the surface of a cutter, so as to still keep physical and mechanical performances of good hardness, low friction coefficient and friction and wear resistance under a high temperature condition.

According to the present invention, the AlCrSiN layers and the MeN layers are alternately and periodically arranged, have adaptivity, and can generate friction oxides in cutting friction, so as to reduce cutting abrasion and prolong the service life of the cutter. According to the present invention, the AlCrSiN layers and the MeN layers are alternately arranged, an outermost layer of a composite coating is changed according to change of thickness of the coating, and the outermost layer may be an AlCrSiN or an MeN layer. As noted above, MeN is the preferred outer layer, but can be AlCrSiN based on thickness requirements.

The present invention also provides a preparation method of the high-temperature-resistant hard composite coating according to the foregoing technical scheme, including the following steps:

(1) depositing a CrN transition layer on the surface of a substrate; and

(2) alternately depositing AlCrSiN layers and MeN layers in sequence on the surface of the CrN transition layer in step (1) (the Me including W, Hb, or Hf), to obtain a high-temperature-resistant hard composite coating.

According to the present invention, a CrN transition layer is deposited on the surface of a substrate. According to the present invention, material of the substrate is optimally hard alloy or high-speed steel, more optimally, hard alloy. There is no special limitation to components of the hard alloy or high-speed steel in the present invention, just hard alloy or high-speed steel familiar to technicians of the field and used for machining may be adopted.

According to the present invention, deposition of the CrN transition layer is optimally cathode arc ion plating deposition. There is no special limitation to an operation of cathode arc ion plating deposition of the CrN transition layer, just a technical scheme for cathode arc ion plating deposition familiar to technicians of the field may be adopted.

According to the present invention, before deposition of the CrN transition layer, optimally, pretreatment and sputtering cleaning are sequentially performed on the substrate. There is no special limitation to operation of the pretreatment, just a technical scheme for pretreatment familiar to a technician of the field may be adopted. According to the present invention, optimally, the pretreatment sequentially includes washing and drying. According to the present invention, the washing optimally includes ultrasonic treatment sequentially performed in acetone and absolute ethyl alcohol; time for ultrasonic treatment sequentially performed in acetone and absolute ethyl alcohol is optimally independently 10˜30 min, more optimally, 15˜25 min. According to the present invention, the drying is optimally drying with clean nitrogen.

According to the present invention, parameters of the sputtering cleaning are optimally: distance between the surface of a substrate and a target material being 10˜25 mm, substrate revolving speed being 3˜9 rpm, temperature being 400˜500° C., sputtering gas being argon, sputtering gas pressure being 1˜1.3 Pa, bias voltage being 800˜1200V, and sputtering cleaning time being 5˜20 min. More optimally: distance between the surface of a substrate and a target material being 15˜20 mm, substrate revolving speed being 5˜7 rpm, temperature being 440˜460° C., sputtering gas being argon, sputtering gas pressure being 1.1˜1.2 Pa, bias voltage being 900˜1100V, and sputtering cleaning time being 10˜15 min. According to the present invention, the sputtering cleaning can improve a binding capacity between a substrate and an CrN transition layer.

According to the present invention, optimally, after the sputtering cleaning is completed, opening a Cr target directly and adjusting all parameters to parameters for cathode arc ion plating deposition of the CrN transition layer to perform deposition of the CrN transition layer. According to the present invention, the parameters for cathode arc ion plating deposition of the CrN transition layer are optimally: distance between the surface of a substrate and a target material being 10˜25 mm, substrate revolving speed being 3˜9 rpm, temperature being 400˜500° C., sputtering gas being argon, sputtering gas pressure being 1.2˜1.8 Pa, reaction gas being nitrogen, reaction gas pressure being 2.0˜2.7 Pa, bias voltage being 140˜200V, arc target current being 40˜80 A, and deposition time being 10˜20 min. More optimally: distance between the surface of a substrate and a target material being 15˜20 mm, substrate revolving speed being 5˜7 rpm, temperature being 440˜460° C., sputtering gas being argon, sputtering gas pressure being 1.4˜1.6 Pa, reaction gas being nitrogen, reaction gas pressure being 2.3˜2.5 Pa, bias voltage being 160˜180V, arc target current being 50˜70 A, and deposition time being 14˜16 min.

After obtaining the CrN transition layer, according to the present invention, AlCrSiN layers and MeN layers are alternately deposited on the surface of the CrN transition layer in sequence, (the Me including W, Hb, or Hf), to obtain a high-temperature-resistant hard composite coating. According to the present invention, deposition of the AlCrSiN layers and MeN layers are respectively multi-arc ion plating deposition and high power pulse magnetron sputtering deposition. According to the present invention, the multi-arc ion plating deposition and high power pulse magnetron sputtering deposition have very high bombarding ion energy, and thus can further improve performances of a coating.

According to the present invention, optimally, after deposition of the CrN transition layer is completed, closing a Cr target, opening an Al_{0.65}Cr_{0.25}Si_{0.1} target, and adjusting parameters to deposition parameters of AlCrSiN layers to perform deposition, and then closing the Al_{0.65}Cr_{0.25}Si_{0.1} target, opening an Me target, and adjusting parameters to parameters for high power pulse magnetron sputtering deposition of the MeN layers to perform deposition, alternately opening and closing the Al_{0.65}Cr_{0.25}Si_{0.1} target and Me target, until completing deposition of the nanocomposite layer.

According to the present invention, parameters for multi-arc ion plating deposition of the AlCrSiN layers are optimally: distance between the surface of a substrate and a target material being 10˜25 mm, substrate revolving speed being 3˜9 rpm, temperature being 400˜500° C., sputtering gas being argon, reaction gas being nitrogen, total gas pressure being 0.7˜1.2 Pa, nitrogen-to-argon pressure ratio being (1˜2):(2˜1), bias voltage being 80˜130V, arc target current being 60˜100 A, and deposition time being 2˜5 min. More optimally: distance between the surface of a substrate and a target material being 15˜20 mm, substrate revolving speed being 5˜7 rpm, temperature being 440˜460° C., sputtering gas being argon, reaction gas being nitrogen, total gas pressure being 0.9˜1.1 Pa, nitrogen-to-argon pressure ratio being 1:1, bias voltage being 100˜110V, arc target current being 70˜90 A, and deposition time being 3˜4 min.

According to the present invention, parameters for high power pulse magnetron sputtering deposition of the MeN layers are optimally: distance between the surface of a substrate and a target material being 10˜25 mm, substrate revolving speed being 3˜9 rpm, temperature being 400˜500° C., sputtering gas being argon, reaction gas being nitrogen, total gas pressure being 0.7˜1.2 Pa, nitrogen-to-argon pressure ratio being (1˜2):(2˜1), bias voltage being 80˜130V, sputtering power being 1.0˜3.0 kW, duty ratio being 1˜5%, peak current being 400˜600 A, and deposition time being 5˜12 min. More optimally: distance between the surface of a substrate and a target material being 15˜20 mm, substrate revolving speed being 5˜7 rpm, temperature being 440˜460° C., sputtering gas being argon, reaction gas being nitrogen, total gas pressure being 0.9˜1.1 Pa, nitrogen-to-argon pressure ratio being 1:1, bias voltage being 90˜110V, sputtering power being 1.5˜2.5 kW, duty ratio being 3˜4%, peak current being 450˜550 A, and deposition time being 8˜10 min.

According to the present invention, optimally, after deposition of the nanocomposite layer is completed, cooling a product of the deposition, to obtain a high-temperature-resistant hard composite coating. According to the present invention, the cooling is optimally performed in an atmosphere of depositing. According to the present invention, the cooling final temperature of the product of the deposition in the atmosphere of depositing is optimally below 150° C., more optimally, below 80° C.

The present invention also provides a coated cutter, including a cutter substrate and a coating disposed on the surface of the cutter substrate. The coating being a high-temperature-resistant hard composite coating according to the foregoing technical scheme or a high-temperature-resistant hard composite coating prepared by a preparation method according to according to the foregoing scheme. According to the present invention, the material of the cutter substrate is optimally hard alloy or high-speed steel. There is no special limitation to components of the hard alloy or high-speed steel in the present invention, just hard alloy or high-speed steel familiar to technicians of the field and used for machining may be adopted. There is no special limitation to the shape and size of the cutter substrate, just a cutter familiar to a technician of the field may be adopted.

According to the present invention, the coated cutter is optimally prepared by taking a cutter substrate as a substrate and preparing according to a preparation method of the high-temperature-resistant hard composite coating according to the foregoing technical scheme, which is not further described herein.

The following describes a high-temperature-resistant hard composite coating, a preparation method thereof and a coated cutter provided by the present invention in details in combination with embodiments, but they cannot be understood as limitation to the protection scope of the present invention.

### Embodiment 1

Performing ultrasonic treatment on a hard alloy cutter substrate for 15 min in acetone by adopting ultrasonic cleaning, then performing ultrasonic treatment for 25 min with absolute ethyl alcohol, and finally drying by blowing with nitrogen;

fixing a machined cutter substrate on a support in a vacuum chamber, with distance to a target material being 15 mm, and support revolving speed being 4 rpm, vacuumizing until ultimate pressure is 1×10⁻³ Pa, then heating a chamber to 400° C., introducing argon so that pressure of the chamber is 1 Pa, and adjusting bias voltage to 800V to perform glow sputtering cleaning for 12 min;

introducing nitrogen to cause pressure to be 2.0 Pa, wherein Ar partial pressure is still 1.3 Pa, starting a Cr target, keeping bias voltage at 140V, arc target current being 40 A, and depositing a CrN transition layer for 14 min;

adjusting a nitrogen and argon flow valve, until total pressure is 0.9 Pa, nitrogen/Ar ratio being 1/1, adjusting substrate bias voltage to 80V, opening an Al_{0.65}Cr_{0.25}Si_{0.1} target, adjusting arc current to 60 A, and preparing an AlCrSiN nanolayer for 3 min;

then closing the Al_{0.65}Cr_{0.25}Si_{0.1} target, opening a W high power pulse magnetron sputtering target, adjusting average sputtering power to 1.4 kW, duty ratio to 2%, and peak current to 45 A, keeping pressure and bias voltage being unchanged, and preparing a WN nanolayer for 8 min; and

alternately opening and closing the Al_{0.65}Cr_{0.25}Si_{0.1} target and the W target like this to prepare a nanocomposite coating AlCrSiN/WN with total thickness of 2.2 μm. Opening the chamber and naturally cooling after preparation of a coating is completed and a vacuum chamber is reduced to 100° C.

Ratio and thickness of the coating according to atomic percent are as follows:

a CrN layer: Cr: 48 at. %, N: 52 at. %; thickness: 80 nm;

an AlCrSiN layer: Al: 39 at. %, Cr: 17 at. %, Si: 6 at. %, N: 38 at. %; single layer thickness: 12 nm; and

a WN layer: W: 49 at. %, N: 51 at. %; single layer thickness: 4 nm.

Total thickness of a prepared nanocomposite coating AlCrSiN/WN is about 2.2 μm, a schematic structure diagram of a coated cutter structure thereof is as shown in FIG. 1, and a cutter structure may be divided into three parts, namely, a cutter substrate, a CrN transition layer and an AlCrSiN/MeN nanocomposite coating.

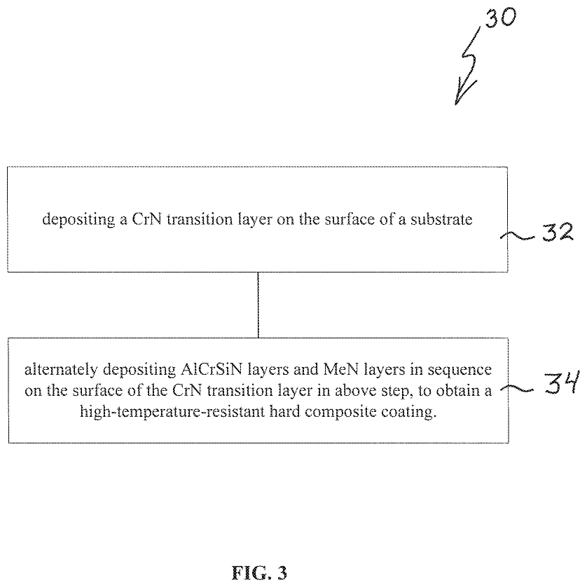

An X ray diffraction image of a coating is as shown in FIG. 2, and it may be obviously seen that diffraction peaks of CrN and WN are of a nanocrystalline structure from full width at half maximum of the diffraction peaks. A phase structure of an AlCrSiN layer is of a nanocomposite structure.

### Comparative Example 1

An AlCrSiN coating deposited on the surface of a similar carbide end mill by adopting a method of embodiment 1.

Perform service life contrast experiment on coated cutters of embodiment 1 and comparative example 1 in high-speed cutting of quenched steel.

Cutting conditions are: cutting speed being 350 m/min; workpiece material being H13 (HRC55˜57); feed rate being 0.06 mm/flute; depth being 0.3 mm, side milling.

Average lifetime being respectively: a cutter with an AlCrSiN coating being 48.0 m; and a cutter with an AlCrSiN/WN being 162.0 m.

### Embodiment 2

Performing ultrasonic treatment on a hard alloy cutter substrate for 15 min in acetone by adopting ultrasonic cleaning, then performing ultrasonic treatment for 25 min with absolute ethyl alcohol, and finally drying by blowing with nitrogen;

fixing a machined cutter substrate on a support in a vacuum chamber, with distance being 15 mm, and support revolving speed being 4 rpm, vacuumizing until ultimate pressure is 1×10⁻³ Pa, then heating a chamber to 400° C., introducing argon so that pressure of the chamber is 1 Pa, and adjusting bias voltage to 800V to perform glow sputtering cleaning for 12 min;

introducing nitrogen to cause pressure to be 2.0 Pa, wherein Ar partial pressure is still 1.2 Pa, starting a Cr target, keeping bias voltage at 120V, arc target current being 40 A, and depositing a CrN transition layer for 14 min;

adjusting a nitrogen and argon flow valve, until total pressure is 0.9 Pa, nitrogen/Ar ratio being 1/1, adjusting substrate bias voltage to 80V, opening an Al_{0.65}Cr_{0.25}Si_{0.1} target, adjusting arc current to 80 A, and preparing an AlCrSiN layer for 5 min;

then closing the Al_{0.65}Cr_{0.25}Si_{0.1} target, opening an Nb high power pulse magnetron sputtering target, adjusting average sputtering power to 2 kW, duty ratio to 1.8%, and peak current to 50 A, keeping pressure and bias voltage being unchanged, and preparing an NbN layer for 10 min;

alternately opening and closing the Al_{0.65}Cr_{0.25}Si_{0.1} target and the Nb target like this to prepare a nanocomposite coating AlCrSiN/NbN with total thickness of 2.5 μm; and

opening the chamber and naturally cooling after preparation of a coating is completed and a vacuum chamber is reduced to 100° C.

Ratio and thickness of the coating according to atomic percent are as follows:

a CrN layer: Cr: 49 at. %, N: 51 at. %; thickness: 70 nm;

an AlCrSiN layer: Al: 38 at. %, Cr: 18 at. %, Si: 7 at. %, N: 37 at. %; single layer thickness: 10 nm;

a NbN layer: Nb: 50 at. %, N: 50 at. %; single layer thickness: 4 nm.

Total thickness of a prepared AlCrSiN/NbN coating is about 2.5 μm.

### Comparative Example 2

AlCrN, AlTiN and AlCrSiN coatings deposited on the surface of a similar carbide end mill by adopting a method of embodiment 2, respectively obtaining end mills with three kinds of coatings.

Perform service life contrast experiment on coated cutters of embodiment 2 and comparative example 2 in high-speed cutting of quenched steel. Cutting conditions are: cutting speed being 350 m/min; workpiece material being H13 (HRC55˜57); feed rate being 0.06 mm/flute; depth being 0.3 mm, side milling.

Average lifetime being respectively: a cutter with an AlCrN coating being 24.0 m, a cutter with an AlTiN coating being 8.2 m, a cutter with an AlCrSiN coating being 48.0 m, and a cutter with an AlCrSiN/NbN being 200.0 m.

### Embodiment 3

Performing ultrasonic treatment on a high-speed steel cutter substrate for 15 min in acetone by adopting ultrasonic cleaning, then performing ultrasonic treatment for 20 min with absolute ethyl alcohol, and finally drying by blowing with nitrogen;

fixing a machined cutter substrate on a support in a vacuum chamber, with distance being 15 mm, and support revolving speed being 3 rpm, vacuumizing until ultimate pressure is 2×10⁻³ Pa, then heating a chamber to 400° C., introducing argon so that pressure of the chamber is 1 Pa, and adjusting bias voltage to 900V to perform glow sputtering cleaning for 15 min;

introducing nitrogen to cause pressure to be 2.0 Pa, wherein Ar partial pressure is still 1.5 Pa, starting a Cr target, keeping bias voltage at 140V, arc target current being 60 A, and depositing a CrN transition layer for 15 min;

adjusting a nitrogen and argon flow valve, until total pressure is 0.9 Pa, nitrogen/Ar ratio being 1/1, adjusting substrate bias voltage to 80V, opening an Al_{0.65}Cr_{0.25}Si_{0.1} target, adjusting arc current to 80 A, and preparing an AlCrSiN layer for 5 min;

then closing the Al_{0.65}Cr_{0.25}Si_{0.1} target, opening an Hf high power pulse magnetron sputtering target, adjusting average sputtering power to 1.8 kW, duty ratio to 2.2%, and peak current to 50 A, keeping pressure and bias voltage being unchanged, and preparing an HfN layer for 6 min;

alternately opening and closing the Al_{0.65}Cr_{0.25}Si_{0.1} target and the Hf target like this to prepare a nanocomposite coating AlCrSiN/HfN with total thickness of 4 μm; and

opening the chamber and naturally cooling after preparation of a coating is completed and a vacuum chamber is reduced to 100° C.

Ratio and thickness of the coating according to atomic percent are as follows:

a CrN layer: Cr: 49 at. %, N: 51 at. %; thickness: 200 nm;
an AlCrSiN layer: Al: 37 at. %, Cr: 18 at. %, Si: 5 at. %, N: 40 at. %; single layer thickness: 15 nm;

a HfN layer: Hf: 48 at. %, N: 52 at. %; single layer thickness: 8 nm.

Total thickness of a prepared AlCrSiN/HfN coating is about 4 μm.

### Comparative Example 3

AlCrN, AlTiN and AlCrSiN coatings deposited on the surface of a similar carbide end mill by adopting a method of embodiment 3, respectively obtaining end mills with three kinds of coatings.

Perform service life contrast experiment on coated cutters of embodiment 3 and comparative example 3 in high-speed cutting of quenched steel.

Cutting conditions are: cutting speed being 350 m/min, workpiece material being H13 (HRC55˜57), feed rate being 0.06 mm/flute, depth being 0.3 mm, side milling.

Average lifetime being respectively: a cutter with an AlCrN coating being 24.0 m; a cutter with an AlTiN coating being 8.2 m; a cutter with an AlCrSiN coating being 48.0 m; and a cutter with an AlCrSiN/HfN being 220.0 m.

It is known from the foregoing comparative examples and embodiments that when the high-temperature-resistant hard composite coating provided by the present invention is applied to the surface of a cutter, the cutter is greatly improved in performances and prolonged in service life.

Descriptions of the foregoing embodiments are merely used for helping to understand the method of the present invention and the core thought thereof. It should be noted that a person of ordinary skill in the art may make some improvements and modifications without departing from the principle of the invention, and these improvements and modifications all fall within the protection scope of the present invention. Various modifications to these embodiments are apparent to professionals of the art, and a general principle defined herein may be implemented in other embodiments under the condition of not departing from the spirit or scope of the present invention. Therefore, the present invention will not be limited to these embodiments shown herein, and conforms to a widest scope consistent to principles and novel characteristics disclosed herein.

1. A high-temperature-resistant hard composite coating, comprising a CrN transition layer and a nanocomposite layer disposed on the surface of a substrate in sequence, the nanocomposite layer comprising AlCrSiN layers and MeN layers alternately arranged on the surface of the CrN transition layer in sequence, and the Me comprising W, Nb, or Hf.

2. The high-temperature-resistant hard composite coating according to claim 1, wherein thickness of each AlCrSiN layer is independently 10˜15 nm.

3. The high-temperature-resistant hard composite coating according to claim 1, wherein the AlCrSiN layer contains 34˜42 at. % of Al, 13˜20 at. % of Cr, 5˜9 at. % of Si and 33˜47 at. % of N according to atomic percent.

4. The high-temperature-resistant hard composite coating according to claim 3, wherein the AlCrSiN layer is of a nanocomposite structure comprising nanocrystalline CrN, amorphous Si3N4 and amorphous AlN.

5. The high-temperature-resistant hard composite coating according to claim 1, wherein thickness of each MeN layer is independently 4˜10 nm.

6. The high-temperature-resistant hard composite coating with according to claim 1, wherein the MeN layer contains 48˜60 at. % of Me and 52˜40 at. % of N according to atomic percent.

7. The high-temperature-resistant hard composite coating according to claim 6, wherein the MeN layer comprises one out of nanocrystallines of WN, NbN and HfN.

8. The high-temperature-resistant hard composite coating according to claim 1, wherein thickness of the nanocomposite layer is 2˜5 μm.

9. The high-temperature-resistant hard composite coating according to claim 1, wherein thickness of the CrN transition layer is 50˜200 nm.

10. A preparation method of the high-temperature-resistant hard composite coating according to claim 1, comprising:
(1) depositing a CrN transition layer on the surface of a substrate; and
(2) alternately depositing AlCrSiN layers and MeN layers in sequence on the surface of the CrN transition layer in step (1), to obtain a high-temperature-resistant hard composite coating.

11. The preparation method according to claim 10, wherein deposition in step (1) is cathode arc ion plating deposition.

12. The preparation method according to claim 10, wherein deposition of the AlCrSiN layer in step (2) is multi-arc ion plating deposition, and deposition of the MeN layer is high power pulse magnetron sputtering deposition.

13. A coated cutter, comprising a cutter substrate and a coating disposed on the surface of the cutter substrate, the coating being a high-temperature-resistant hard composite coating according to claim 1.

14. The high-temperature-resistant hard composite coating according to claim 2, wherein the AlCrSiN layer contains 34˜42 at. % of Al, 13˜20 at. % of Cr, 5˜9 at. % of Si and 33˜47 at. % of N according to atomic percent.

15. The high-temperature-resistant hard composite coating according to claim 14, wherein the AlCrSiN layer is of a nanocomposite structure comprising nanocrystalline CrN, amorphous Si3N4 and amorphous AN.

16. The high-temperature-resistant hard composite coating with according to claim 5, wherein the MeN layer contains 48˜60 at. % of Me and 52˜40 at. % of N according to atomic percent.

17. The high-temperature-resistant hard composite coating with according to claim 16, wherein the MeN layer contains 48˜60 at. % of Me and 52˜40 at. % of N according to atomic percent.

18. The preparation method of the high-temperature-resistant hard composite coating according to claim 2, comprising:
(1) depositing a CrN transition layer on the surface of a substrate; and
(2) alternately depositing AlCrSiN layers and MeN layers in sequence on the surface of the CrN transition layer in step (1), to obtain a high-temperature-resistant hard composite coating.

19. The preparation method of the high-temperature-resistant hard composite coating according to claim 3, comprising:
(1) depositing a CrN transition layer on the surface of a substrate; and
(2) alternately depositing AlCrSiN layers and MeN layers in sequence on the surface of the CrN transition layer in step (1), to obtain a high-temperature-resistant hard composite coating.

20. A coated cutter, comprising a cutter substrate and a coating disposed on the surface of the cutter substrate, the coating being a high-temperature-resistant hard composite coating prepared by the preparation method according to claim 10.
